(19) United States
(12) Patent Application Publication
(10) Pub. No.: US 2009/0315570 A1
(43) Pub. Date: Dec. 24, 2009

(54) CAPACITIVE SENSING DEVICE

(76) Inventors: Mark Lynsin David Chappell, Los Altos, CA (US); Bob Lee Mackey, San Jose, CA (US)

Correspondence Address: SYNAPTICS C/O WAGNER BLECHER LLP, 123 WESTRIDGE DRIVE, WATSONVILLE, CA, 95076, US

(21) Appl. No.: 12/144,323

(22) Filed: Jun. 23, 2008

(51) Int. Cl. G01R 27/26

(52) U.S. Cl. 324/661

(57) ABSTRACT

A capacitive sensing device including a substrate, a sensor electrode disposed over the substrate, a first trace electrically coupled to the sensor electrode, and a second trace proximate the first trace. The second trace is for distinguishing proximity of an object with the sensor electrode from proximity of the object with the first trace.

### BACKGROUND

Capacitive sensing devices, otherwise known as touch sensing devices or proximity sensors are widely used in modern electronic devices. A capacitive sensing device is often used for navigation, selection, or other input, in response to a finger, stylus, or other object being placed on or in proximity to a sensor of the capacitive sensing device. In such a capacity, capacitive sensing devices are often employed in computers (e.g. notebook/laptop computers), media players, multi-media devices, remote controls, personal digital assistants, smart devices, telephones, and the like.

Capacitive sensing devices often include sensor conductors, including at least one sensor electrode and routing trace that are coupled to a controller. A potential performance issue arises when routing traces are unshielded. Users interacting with the unshielded routing traces may induce artifacts (e.g., noise) into the capacitive sensing device. For example, the capacitive sensing device may not be able to distinguish interactions with only a routing trace from interactions with a sensor electrode. Moreover, where the routing trace is next to another sensor electrode, it might appear as if a user is interacting with two sensor electrodes.

### SUMMARY

Various embodiments of the present invention, a capacitive sensing device, are described herein. In one embodiment, a capacitive sensing device including a substrate, a sensor electrode disposed over the substrate, a first trace electrically coupled to the sensor electrode, and a second trace proximate the first trace, is described. The second trace is for distinguishing proximity of an object with the sensor electrode from proximity of the object with the first trace.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1A shows a plan view of capacitive sensing device including a sensor conductor and a differential trace, in accordance with an embodiment of the present invention.

FIG. 1B shows a plan view of capacitive sensing device including a sensor conductor and two differential traces, in accordance with an embodiment of the present invention.

FIG. 2A shows a plan view of capacitive sensing device including two sensor conductors and two differential traces, in accordance with an embodiment of the present invention.

FIG. 2B shows a plan view of capacitive sensing device including two sensor conductors and a differential trace, in accordance with an embodiment of the present invention.

FIG. 3 is a flowchart diagram illustrating steps in a process for capacitive sensing, in accordance with one embodiment of the present invention.

### DESCRIPTION OF EMBODIMENTS

Reference will now be made in detail to the various embodiments of the invention, examples of which are illustrated in the accompanying drawings. While the invention will be described in conjunction with the various embodiments, it will be understood that they are not intended to limit the invention to these embodiments. On the contrary, the invention is intended to cover alternatives, modifications and equivalents, which may be included within the spirit and scope as defined by the appended claims. Furthermore, in the following description of various embodiments, numerous specific details are set forth in order to provide a thorough understanding of embodiments of the present invention. In other instances, well-known methods, procedures, components, and circuits have not been described in detail so as not to unnecessarily obscure aspects of embodiments of the present invention.

Various embodiments of the present invention, a capacitive sensing device, are described herein. In one embodiment, a capacitive sensing device including a substrate, a sensor electrode disposed over the substrate, a first routing trace electrically coupled to the sensor electrode, and a second trace proximate the first trace, is described. The second trace is for distinguishing proximity of an object with the sensor electrode from proximity of the object with the first trace. In one embodiment, based on signals received from the first trace and the second trace, it can be determined whether the object is proximate the first trace. Once detected, these signals can be processed to determine whether they are causing interference and can selectively be filtered or cancelled out.

### Capacitive Sensing Device

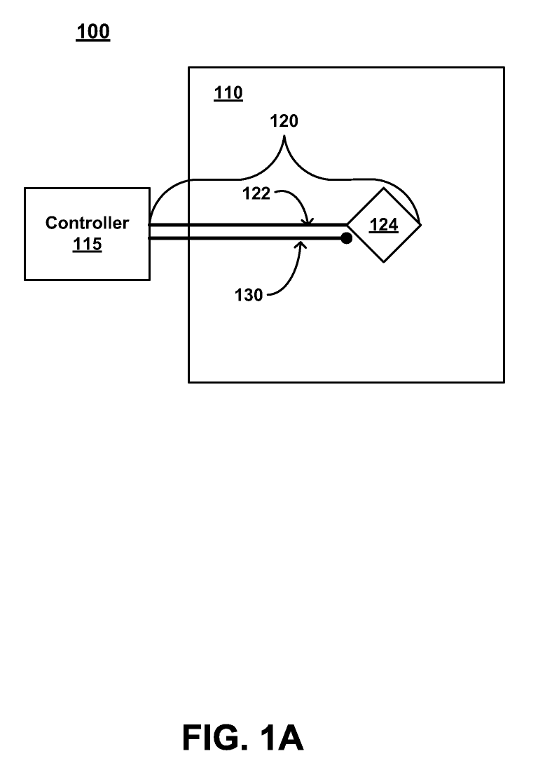

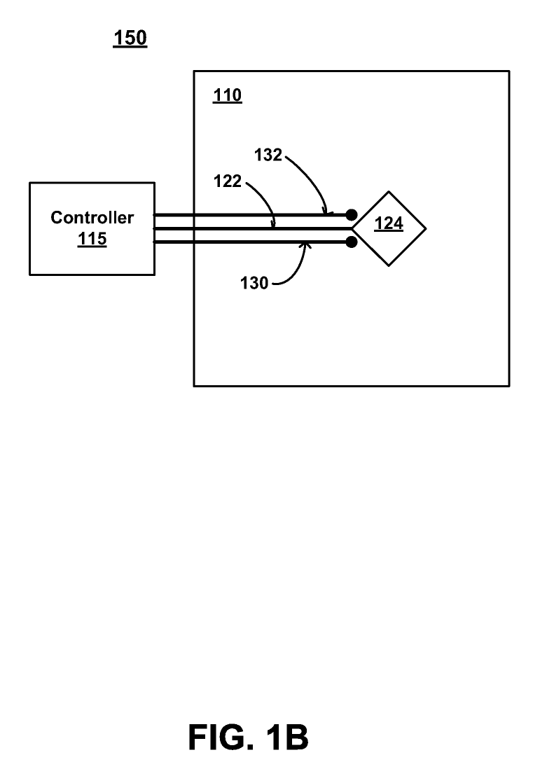

FIG. 1A shows a plan view of capacitive sensing device 100, in accordance with an embodiment of the present invention. Capacitive sensing device 100 includes substrate 110, routing trace 122, sensor electrode 124, differential trace 130, and controller 115. It should be appreciated that capacitive sensing device 100 may include any number of routing traces, sensor electrodes and differential traces, as described herein and in the following various embodiments.

It should be appreciated that substrate 110 can be comprised of any material capable of receiving electrical conductive traces. In one embodiment, substrate 110 is comprised of materials such as, for example, glass or polyethylene terephthalate (PET). In one embodiment, substrate 110 is non-opaque. In one embodiment, substrate 110 is substantially transparent.

For purposes of the instant description, a routing trace and a sensor electrode are collectively referred to as a sensor conductor. For example, sensor conductor 120 includes routing trace 122 and sensor electrode 124. It should be appreciated that the routing trace and sensor electrode components of a sensor conductor refer to the structural implementation, and generally do not refer to the electrical conductivity of the sensor conductor. For instance, the sensor electrode refers to the portion of the sensor conductor that is expected to detect proximity of an object used for interacting with the capacitive sensing device, e.g., a finger or a stylus. The routing trace refers to the portion of the sensor conductor that electrically couples the sensor electrode to the controller.

However, in certain circumstances, e.g., where the routing traces are unshielded, proximity of an object with the routing trace can introduce artifacts into the capacitive sensing device. For example, the capacitive sensing device may not be able to distinguish contact with the routing trace from contact with the sensor electrode. Moreover, where the routing trace is next to another sensor electrode, it might appear as if a user is making contact with two sensor electrodes.

It should be appreciated that routing traces may be unshielded for many reasons, such as for optical reasons. For example, the capacitive sensing device may not include a shielding layer for the routing trace when the routing trace area is visible to users. In another example, the routing traces may include a non-opaque material, such as indium tin oxide (ITO) to reduce visual artifacts, but ITO still reduces optical performance. In addition, including a shield may lead to increased cost. Alternatively, a bezel may not be an appropriate shield as it may block the user's view of the display screen. Embodiments of the present invention provide a capacitive sensing device that does not require an extra shielding layer above routing traces, for preventing artifacts being sensed by the capacitive sensing device.

Sensor electrode 124 is configured to detect an object, e.g., a finger or a stylus, proximate sensor electrode 124, and transmit a signal over routing trace 122 to controller 115 in response to detecting an object. However, any portion of sensor conductor 120, including routing trace 122, can detect a proximate object and transmit a signal to controller 115. Therefore, a signal received at controller 115 might not be generated due to proximity of an object with sensor electrode 124.

Differential trace 130 is located over substrate 110 and is proximate routing trace 122. For example, differential trace 130 is located next to routing trace 122. In one embodiment, differential trace 130 is located proximate routing trace 122 at a distance that maintains electrical isolation, but allows for detection an object proximate routing trace 122. Differential trace 130 is configured to detect an object proximate differential trace 130, and transmit a signal to controller 115 in response to detecting an object. Differential trace 130 is for distinguishing proximity of an object with sensor electrode 124 from proximity of the object with routing trace 122.

It should be appreciated that the description of differential trace 130 being proximate routing trace 122 refers to differential trace 130 being located close to routing trace 122. For example, differential trace 130 and routing trace 122 are proximate with regard to the detection of an object placed in proximity of differential trace 130 and routing trace 122. In other words, routing trace 122 and differential trace 130 should be close enough to each other such that both would detect an object placed in proximity.

Moreover, it should be appreciated that proximity of an object to capacitive sensing device 100 refers to the object, e.g., a finger or a stylus, interacting with capacitive sensing device 100. It is not necessary that the object make actual physical contact with any surface associated the capacitive sensing device 100 associated. For example, capacitive sensing device 100 may include a cover layer disposed over the sensor electrodes, differential trace 130, routing trace 122, and other componentry for protection purposes, and the surface associated with input to the capacitive sensing device 100 can be of this cover layer. In some cases, the object need not contact the cover layer to provide input.

In one embodiment, sensor electrode 124, routing trace 122, and differential trace 130 are disposed over substrate 110. In other embodiments, sensor electrode 124, routing trace 122, and differential trace 130 are disposed on substrate 110. It should be appreciated that in various embodiments, additional layers may be placed over substrate 110. Moreover, it should be appreciated that sensor electrode 124, routing trace 122, and differential trace 130 may be individually or collectively located on or over substrate 100, depending on the specific implementation.

In one embodiment, controller 115 is electrically coupled to routing trace 122 and to differential trace 130. It should be appreciated that controller 115 can be any type of electronic device for receiving and controlling data, such as a microcontroller. In one embodiment, controller 115 is an application-specific integrated circuit (ASIC) for controlling capacitive sensing device 100 and for providing an interface between capacitive sensing device 100 and an electronic device.

Moreover, it should be appreciated that controller 115 may include any number of channels for receiving signals from electrically coupled traces. While embodiments of the present invention are described with particular numbers of channels, it should be appreciated that controller 115 may include any number of channels.

Controller 115 is for receiving a first signal from routing trace 122 and a second signal from differential trace 130. In one embodiment, controller 115 is operable to distinguish proximity of an object with routing trace 122 from proximity of the object with sensor electrode 124, based at least in part on the first signal and the second signal.

In one embodiment, controller 115 is operable to distinguish proximity of an object with routing trace 122 from proximity of the object with sensor electrode 124 based at least in part on magnitudes of the first signal and the second signal. For instance, in one embodiment, provided the second signal is satisfies a threshold, it is determined that the object is proximate sensor electrode 124.

In one embodiment, controller 115 is operable to distinguish proximity of the object with routing trace 122 from proximity of the object with sensor electrode 124 based at least in part on a difference of magnitudes of the first signal and the second signal. For example, in one embodiment, provided the difference of the magnitudes of the first signal and the second signal satisfies a threshold, it is determined that the object is proximate sensor electrode 124.

In one embodiment, controller 115 is disabled in response to receiving the first signal and the second signal, and the failure of a predetermined test. In other words, in response to determining that the object is proximate routing trace 122 and not sensor electrode 124, controller 115 is disabled.

In one embodiment, responsive to determining the object is not proximate routing trace 122, and therefore proximate sensor electrode 124, an action is initiated (e.g., a selection).

In various embodiments of the present invention, each routing trace is associated with multiple differential traces, for the purpose of enhancing the detection of artifacts. FIG. 1B shows a plan view of capacitive sensing device 150 including a sensor conductor and two differential traces, differential trace 130 and differential trace 132, in accordance with an embodiment of the present invention. It should be appreciated that substrate 110, routing trace 122, sensor electrode 124, differential trace 130, and controller 115 of capacitive sensing device 150 operate in a similar manner as described above in accordance with capacitive sensing device 100 of FIG. 1A.

In one embodiment, capacitive sensing device 150 further includes differential trace 132 proximate routing trace 122 on an opposing side of routing trace 122 as differential trace 130. Differential trace 132 is configured for distinguishing proximity of an object with sensor electrode 124 from proximity of the object with routing trace 122. In one embodiment, differential trace 130 and differential trace 132 are on the same side of substrate 110.

By locating a differential trace on both sides of routing trace 122, capacitive sensing device increases the sensitivity of capacitive sensing device 150, with regard to detecting artifacts. For example, with reference to FIG. 1A, it is possible that proximity of an object with routing trace 122 and not differential sensor 130 is detected. Such detection might result in a false reading. For example, if an object is detected by routing trace 122 but not by differential trace 130, controller 115 might make a false determination of proximity with sensor electrode 124.

With reference to FIG. 1B, differential traces 130 and 132 are located on both sides of routing trace 122. The present embodiment reduces the chances of incorrect detection of proximity of the object with routing trace 122. However, it should be appreciated that the present embodiment requires an additional sensing channel over the embodiments illustrated in FIG. 1A.

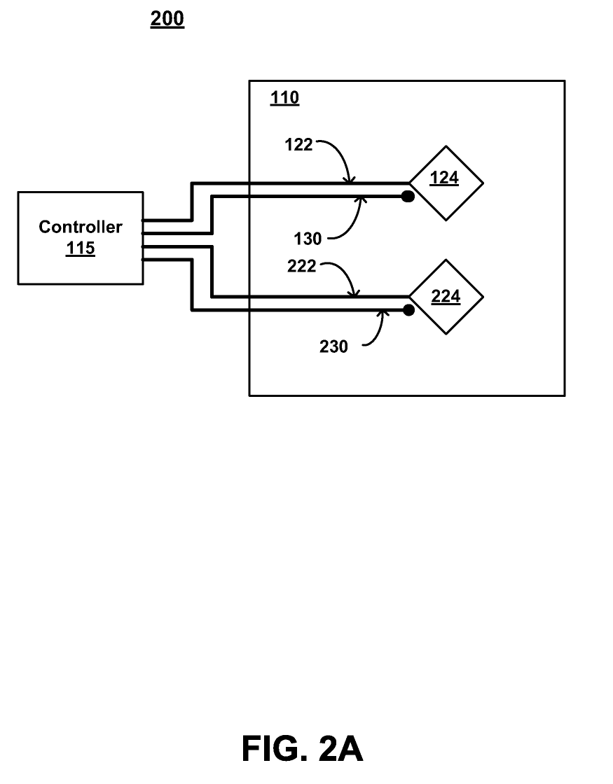

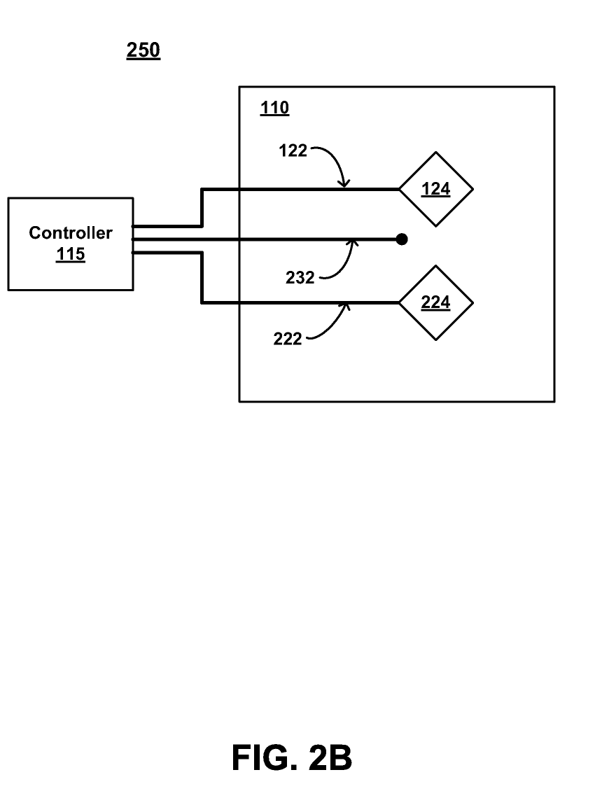

As presented above, various embodiments of the present invention may include multiple sensor conductors. FIG. 2A shows a plan view of capacitive sensing device 200 including two sensor conductors and two differential traces, in accordance with an embodiment of the present invention. It should be appreciated that substrate 110, routing trace 122, sensor electrode 124, differential trace 130, and controller 115 of capacitive sensing device 150 operate in a similar manner as described above in accordance with capacitive sensing device 100 of FIG. 1A.

Capacitive sensing device 200 also includes routing trace 222, sensor electrode 224, and differential trace 230. Differential trace 230 is for distinguishing proximity of an object with sensor electrode 224 from proximity of the object with routing trace 222.

Controller 115 is configured to receive a signal from routing trace 222 and a signal from differential trace 230. In one embodiment, controller 115 is operable to distinguish proximity of an object with routing trace 222 from proximity of the object with sensor electrode 224, based at least in part on the signals. In one embodiment, controller 115 is operable to distinguish proximity of an object with routing trace 222 from proximity of the object with sensor electrode 224 based at least in part on magnitudes of the signals. In one embodiment, controller 115 is operable to distinguish proximity of the object with routing trace 222 from proximity of the object with sensor electrode 224 based at least in part on a difference of magnitudes of the signals.

FIG. 2B shows a plan view of capacitive sensing device including two sensor conductors and a shared differential trace, in accordance with an embodiment of the present invention. It should be appreciated that substrate 110, routing trace 122, sensor electrode 124, routing trace 222, sensor electrode 224, and controller 115 of capacitive sensing device 250 operate in a similar manner as described above in accordance with capacitive sensing device 100 of FIG. 1A and capacitive sensing device 200 of FIG. 2A.

Capacitive sensing device 250 also includes differential trace 232. Differential trace 232 is for distinguishing proximity of an object with sensor electrode 124 from proximity of the object with routing trace 122 and for distinguishing proximity of an object with sensor electrode 224 from proximity of the object with routing trace 222.

Differential trace 232 is located proximate routing trace 122 and routing trace 222. It should be appreciated that embodiments of the present invention may be directed toward a single differential trace being associated with any number of routing traces. By sharing a single differential trace across a plurality of routing traces, the number of channels of the microcontroller can be reduced. However, in order to efficiently implement such an embodiment, it might be necessary to arrange the shared differential trace such that it is not proximate with a sensor electrode.

Controller 115 is configured to receive signals from routing trace 122, routing trace 222 and differential trace 232. In one embodiment, controller 115 is operable to distinguish proximity of an object with routing trace 122 from proximity of the object with sensor electrode 124, based at least in part on the signals. In one embodiment, controller 115 is operable to distinguish proximity of an object with routing trace 222 from proximity of the object with sensor electrode 224, based at least in part on the signals.

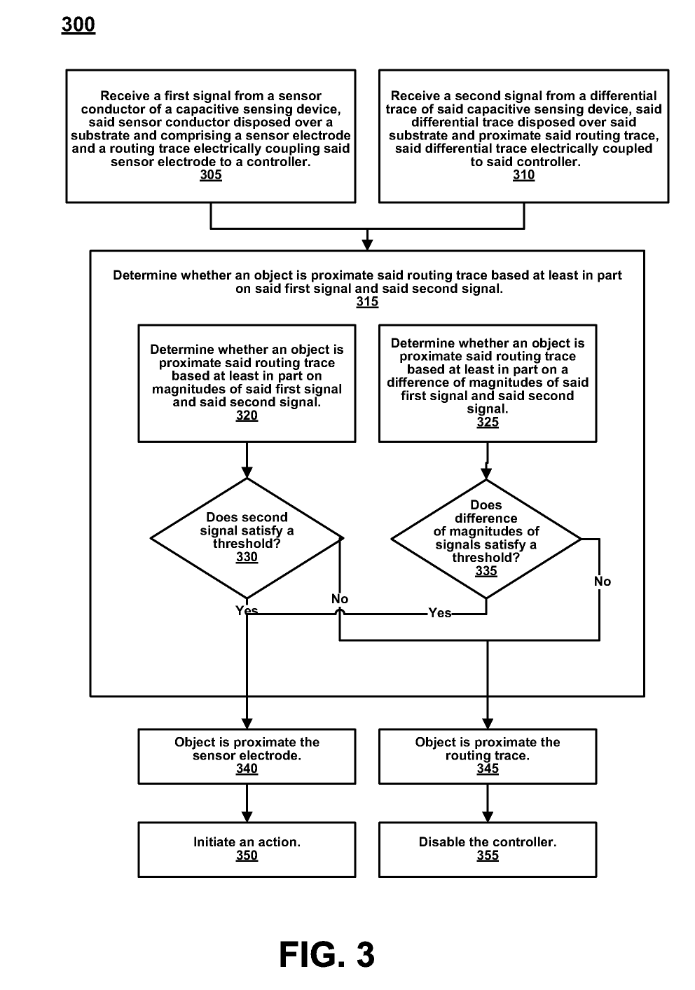

FIG. 3 is a flowchart illustrating a process 300 for capacitive sensing in accordance with an embodiment of the present invention. Although specific operations are disclosed in process 300, such steps are exemplary. That is, embodiments of the present invention are well-suited to performing various other operations or variations of the operations recited in process 300. The operations in process 300 may be performed in an order different than presented, and it is possible that not all of the operations in process 300 are performed. All of, or a portion of, the operations described by process 300 may be implemented using computer-readable and computer-executable instructions which reside, for example, in computer-usable media of a computer system. In one embodiment, process 300 is performed in controller 115 of FIGS. 1A, 1B, 2A and 2B.

At block 305, a first signal is received from a sensor conductor of a capacitive sensing device. The sensor conductor is disposed over a substrate and includes a sensor electrode and a routing trace electrically coupling the sensor electrode to a controller.

At block 310, a second signal is received from a differential trace of the capacitive sensing device. The differential trace is disposed over the substrate and proximate the routing trace, and the differential trace electrically coupled to the controller.

At block 315, it is determined whether an object is proximate the routing trace based at least in part on the first signal and the second signal.

In one embodiment, as shown at block 320, it is determined whether an object is proximate the routing trace based at least in part on magnitudes of the first signal and the second signal. At block 330, it is determined whether the second signal satisfies a threshold. In one embodiment, a threshold is satisfied if the magnitude of the second signal is less than the threshold value. For example, in order to indicate proximity with the routing trace, the second signal is determined to be greater than a threshold value. In one embodiment, it is determined that the object is proximate the sensor electrode if the second signal is below a threshold.

As shown at block 340, if it is determined that the second signal does satisfy a threshold, it is determined that the object is proximate the sensor electrode. Alternatively, as shown at block 345, if it is determined that the second signal does not satisfy a threshold, it is determined that the object is proximate the routing trace.

In another embodiment, as shown at block 325, it is determined whether an object is proximate the routing trace based at least in part on a difference of magnitudes of the first signal and the second signal. At block 335, it is determined whether the difference of magnitudes satisfies a threshold. In one embodiment, a threshold is satisfied if the difference of magnitudes is greater than the threshold value. For example, in order to indicate proximity with the routing trace, the difference of magnitudes is determined to be less than a threshold value. In other words, if the object is proximate both the routing trace and the differential trace, then the difference of magnitudes should be small. In one embodiment, it is determined that the object is proximate the sensor electrode if the difference in magnitudes is above a threshold.

As shown at block 340, if it is determined that the second signal does satisfy a threshold, it is determined that the object is proximate the sensor electrode. Alternatively, as shown at block 345, if it is determined that the second signal does not satisfy a threshold, it is determined that the object is proximate the routing trace.

In one embodiment, as shown at block 350, if the object is proximate the sensor electrode, an action is initiated. For example, an action might be a user selection.

In one embodiment, if the object is proximate the routing trace, no action is taken. In one embodiment, as shown at block 355, if the object is proximate the routing trace, the controller is disabled. For example, disabling the controller prevents erroneous data to be generated as a result of contact with the routing trace.

Various embodiments of the present invention, a capacitive sensing device, are thus described. While the present invention has been described in particular embodiments, it should be appreciated that the present invention should not be construed as limited by such embodiments, but rather construed according to the below claims.

What is claimed is:

1. A capacitive sensing device comprising:
a substrate;
a sensor electrode disposed over said substrate;
a first trace electrically coupled to said sensor electrode; and
a second trace proximate said first trace, said second trace for distinguishing proximity of an object with said sensor electrode from proximity of said object with said first trace.

2. The capacitive sensing device of claim 1 wherein said first trace, said second trace and said substrate are comprised of non-opaque material.

3. The capacitive sensing device of claim 1 wherein said first trace, said second trace and said substrate are comprised of a substantially transparent material.

4. The capacitive sensing device of claim 1 wherein said first trace and said second trace are disposed on said substrate.

5. The capacitive sensing device of claim 1 further comprising:
a third trace proximate said first trace on an opposing side of said first trace as said second trace, said third trace for distinguishing proximity of said object with said sensor electrode from proximity of said object with said first trace.

6. The capacitive sensing device of claim 5 wherein said first trace and said second trace are disposed on a same side of said substrate.

7. The capacitive sensing device of claim 1 further comprising:
a second sensor electrode disposed over said substrate;
a third trace electrically coupled to said second sensor electrode; and
a fourth trace proximate said third trace, said fourth trace for distinguishing proximity of an object with said second sensor electrode from proximity of said object with said third trace.

8. The capacitive sensing device of claim 1 further comprising:
a second sensor electrode disposed over said substrate; and
a third trace electrically coupled to said second sensor electrode;
wherein said second trace is proximate said third trace, said second trace for distinguishing proximity of said object with said second sensor electrode from proximity of said object with said third trace.

9. The capacitive sensing device of claim 1 further comprising:
a controller electrically coupled to said first trace and to said second trace, said controller for receiving a first signal from said first trace and a second signal from said second trace.

10. The capacitive sensing device of claim 9 wherein said controller is operable to distinguish proximity of said object with said first trace from proximity of said object with said sensor electrode based at least in part on said first signal and said second signal.

11. The capacitive sensing device of claim 10 wherein said controller is operable to distinguish proximity of said object with said first trace from proximity of said object with said sensor electrode based at least in part on magnitudes of said first signal and said second signal.

12. The capacitive sensing device of claim 10 wherein said controller is operable to distinguish proximity of said object with said first trace from proximity of said object with said sensor electrode based at least in part on a difference of magnitudes of said first signal and said second signal.

13. The capacitive sensing device of claim 9 wherein said controller is disabled in response to receiving said first signal and said second signal.

14. A method for capacitive sensing, said method comprising:
receiving a first signal from a sensor conductor of a capacitive sensing device, said sensor conductor disposed over a substrate and comprising a sensor electrode and a routing trace electrically coupling said sensor electrode to a controller;
receiving a second signal from a differential trace of said capacitive sensing device, said differential trace disposed over said substrate and proximate said routing trace, said differential trace electrically coupled to said controller; and
determining whether an object is proximate said routing trace based at least in part on said first signal and said second signal.

15. The method of claim 14 wherein said determining whether an object is proximate said routing trace based at least in part on said first signal and said second signal comprises:
determining whether an object is proximate said routing trace based at least in part on magnitudes of said first signal and said second signal.

16. The method of claim 15 further comprising:
provided said second signal satisfies a threshold, determining that said object is proximate said sensor electrode.

17. The method of claim 14 wherein said determining whether an object is proximate said routing trace based at least in part on said first signal and said second signal comprises:
determining whether an object is proximate said routing trace based at least in part on a difference of magnitudes of said first signal and said second signal.

18. The method of claim 17 further comprising:
provided said difference of said magnitudes of said first signal and said second signal satisfies a threshold, determining that said object is proximate said sensor electrode.

19. The method of claim 14 further comprising:
responsive to determining said object is proximate said routing trace, disabling said controller.

20. The method of claim 14 further comprising:
responsive to determining said object is not proximate said routing trace, initiating an action.

21. A capacitive sensing device comprising:
a substrate comprised of a non-opaque material;
a controller;
a sensor conductor disposed on said substrate, said sensor conductor comprising:
a sensor electrode; and
a routing trace disposed electrically coupling said sensor electrode to said controller; and
a differential trace electrically disposed on said substrate and coupled to said controller, said differential trace proximate said routing trace, said differential trace for distinguishing proximity of an object with said sensor electrode from proximity of said object with said routing trace;
wherein said controller is operable to distinguish proximity of said object with said routing trace from proximity of said object with said sensor electrode based at least in part on a routing signal received from said routing trace and a differential signal received from said differential trace.

22. The capacitive sensing device of claim 21 further comprising:
a second differential trace disposed on said substrate proximate said routing trace on an opposite side of said routing trace as said differential trace, said second differential trace electrically coupled to said controller and for distinguishing proximity of said object with said sensor electrode from proximity of said object with said routing trace.

23. The capacitive sensing device of claim 21 further comprising:
a second sensor electrode disposed on said substrate;
a second routing trace electrically coupled to said second sensor electrode and to said controller; and
a second differential trace proximate said second routing trace, said second differential trace electrically coupled to said controller and for distinguishing proximity of an object with said second sensor electrode from proximity of said object with said second routing trace.

24. The capacitive sensing device of claim 21 further comprising:
a second sensor electrode disposed on said substrate; and
a second routing trace electrically coupled to said second sensor electrode and to said controller;
wherein said differential trace is proximate said second routing trace, said differential trace for distinguishing proximity of said object with said second sensor electrode from proximity of said object with said second routing trace.
